(19) United States
(12) Patent Application Publication
(10) Pub. No.: US 2006/0181362 A1
(43) Pub. Date: Aug. 17, 2006

(54) Voltage-controlled oscillator and RF-IC

(76) Inventors: Isao Ikuta, Yokohama (JP); Akio Yamamoto, Hiratsuka (JP); Yusaku Katsube, Yokohama (JP); Toshiya Uozumi, Takasaki (JP); Yasuyuki Kimura, Maebashi (JP)

Correspondence Address: MCDERMOTT WILL & EMERY LLP, 600 13TH STREET, N.W., WASHINGTON, DC, 20005-3096, US

(21) Appl. No.: 11/280,819

(22) Filed: Nov. 17, 2005

(30) Foreign Application Priority Data
Feb. 15, 2005 (JP) 2005-037007

(51) Int. Cl. H03B 5/08

(52) U.S. Cl. 331/167

(57) ABSTRACT

There are provided a voltage-controlled oscillator and an RF-IC for W-CDMA, which are capable of ensuring a wide frequency range and improving oscillation stability. The voltage-controlled oscillator (RF-IC) includes: switching A and B inductors generating a magnetic interaction between resonant A and B inductors of a resonant circuit; and an A_NMOS, a B_NMOS, a C_NMOS, and D_NMOS as switch/load means having together a function of changing an inductance value by the magnetic interaction between the resonant A and B inductors and the switching A and B inductors and a function of serving as loads of the switching A and B inductors. The A_NMOS, the B_NMOS, the C_NMOS, and the D_NMOS are turned ON/OFF by a control signal so as to control the mutual induction, whereby the oscillation frequency is switched by changing the inductance value of the resonant circuit. Also, oscillation stability is improved by increasing the inductance value.

### CROSS-REFERENCE TO RELATED APPLICATION

The present application claims priority from Japanese patent application No. JP 2005-37007 filed on Feb. 15, 2005, the content of which is hereby incorporated by reference into this application.

### BACKGROUND OF THE INVENTION

The present invention relates to a voltage-controlled oscillator and, particularly, to a technique effectively applied to a voltage-controlled oscillator and an RF-IC for W-CDMA, which include a semiconductor integrated circuit formed on a semiconductor substrate.

For example, the voltage-controlled oscillator can vary its oscillation frequency by applying a control voltage to a variable capacitance and changing a value of the capacitance and therefore has been widely used in an area of communications such as mobile terminals and television tuners. In GSM currently used mainly as a European mobile terminal system, a frequency band of 800 MHz to 900 MHz and a frequency band of 1800 MHz to 1900 MHz are employed. In the case of a direct conversion system, however, a oscillation frequency range of the voltage-controlled oscillator is such that a difference in frequency after multiplication is in the order of 500 MHz. Thus, for the purpose of changing the oscillation frequency, it is sufficient in practice to switch the variable capacitance and the fixed capacitance.

However, in the case of W-CDMA which is a third-generation mobile terminal system and a commercial service having begun recently, the frequency range becomes in the order of 840 MHz and, in consideration of manufacture tolerances, an oscillation frequency range of 1 GHz or more is required. To solve this problem, systems have been taken in which, for example, a plurality of voltage-controlled oscillators are provided or only a plurality of resonant circuits are provided. However, in a mobile terminal market where further downsizing and cost reduction are progressing, problems in size and cost arise. Meanwhile, if making vales of inductance and areas of inductors smaller brings an advantage in terms of an area, but no negative resistance occurs due to characteristic deterioration of a transistor at a time of high temperatures or manufacture, whereby a Q factor of the inductor becomes lower and the oscillation stability is not ensured at a time of lower oscillation frequency, which results in the possibility of causing the oscillation to stop.

An example of a technique of variable frequency by a mutual induction is disclosed in Patent Document 1 (Japanese Patent Laid-Open Publication No. 2002-151953). In this technique, the inductance value is varied through mutual induction by a main inductor and a sub-inductor, whereby the frequency are varied.

### SUMMARY OF THE INVENTION

In the above-mentioned voltage-controlled oscillator, however, there is a problem in which a frequency-variable range of the voltage-controlled oscillator cannot be widened to 1 GHz or more due to limitations of a parasitic capacitance added to the resonant circuit and a voltage level to be applied to the variable capacitance. Moreover, no negative resistance occurs due to deterioration in characteristic of the transistor at the time of high temperature and manufacture and the Q factor of the inductor is reduced, whereby there is a problem of being unable to ensure the oscillation stability.

Also, in the above-mentioned technique by the Patent Document 1, the frequency is varied by changing the values of inductance through the mutual induction between the main inductor and the sub-inductor. As a basic configuration, however, the sub-inductor has no load. Moreover, the sub-inductor has no changing switch depending on the capacitance for dealing with a plurality of channels required for the mobile terminal such as a type of GMS, so that this technique is not suitable for the W-CDMA mobile terminal system.

Therefore, an object of the present invention is to provide a voltage-controlled oscillator and an RF-IC for W-CDMA, which can obtain a wide frequency range and improve the oscillation stability.

The above and other objects and features of the present invention will become apparent from the description of this specification and the accompanying drawings.

Outlines of representative ones of the inventions disclosed in the present application will be briefly described as follows.

The present invention is applied to a voltage-controlled oscillator, which is provided with a resonant circuit configured by a resonant inductor and a resonant capacitance, and an active component forming negative resistance and is formed on a semiconductor substrate, the voltage-controlled oscillator comprising: a sub inductor for changing a value of a resonant inductance and generating a magnetic interaction with the resonant inductor; and switching/load means having together a switching function of changing an inductance value by the magnetic interaction between the resonant inductor and the sub inductor, a load function of serving as a load of the sub inductor, and a function of changing a value of the resonant capacitance, wherein an oscillation frequency is switched by changing the inductance value and the value of the resonant capacitance.

The present invention is also applied to the same voltage-controlled oscillator as the above-mentioned oscillator, the voltage-controlled oscillator comprising: a sub inductor for changing a value of a resonant inductance and generating a magnetic interaction with the resonant inductor; and switching/load means having together a switching function of increasing an inductance value by the magnetic interaction between the resonant inductor and the sub inductor, and a load function of serving as a load of said sub inductor, wherein oscillation stability is improved by increasing the inductance value.

Further, in the voltage-controlled oscillator, a circuit formed by the sub inductor and the switch/load means is a closed circuit. The negative resistance is formed by one of an NMOS/PMOS transistor and an NPN/PNP transistor. The resonant capacitance is formed by a variable capacitance and a fixed capacitance. The switch/load means are formed by one of a varicap and an NMOS/PMOS transistor or by a MOS transistor.

In addition, the present invention is applied to an RF-IC of W-CDMA system, wherein an inductance of a controlled oscillator generating a local signal to be supplied to a direct-down MIXER or a direct-up MIXER is configured by a primary coil and a secondary coil M-coupled to each other, and an oscillation of a high frequency is determined by an inductance of the primary coil and an oscillation of a low frequency is determined by the primary coil and secondary coil and a mutual inductance. Or, oscillation stability of a low frequency is improved by the primary coil and secondary coil and a mutual inductance.

Effects obtained from representative ones of the inventions disclosed in the present application will be briefly descried as follows.

In the voltage-controlled oscillator and the RF-IC according to the present invention, the inductance value is changed by the mutual induction, whereby a frequency range wider than an oscillation frequency changing range obtained by a variable capacitance and a fixed capacitance can be ensured. Also, by increasing the inductance value by the mutual induction, the oscillation stability can be improved.

### DESCRIPTION OF THE DRAWINGS

FIG. 1 is a circuit diagram showing a configuration of a voltage-controlled oscillator according to a first embodiment of the present invention.

FIG. 2 is a view showing a frequency characteristic before changing an inductance value by mutual induction in the voltage-controlled oscillator according to the first embodiment of the present invention.

FIG. 3 is a view showing a frequency characteristic after changing an inductance value by mutual induction in the voltage-controlled oscillator according to the first embodiment of the present invention.

FIG. 4 is a circuit diagram showing another example of a resonant capacitor in the voltage-controlled oscillator according to the first embodiment of the present invention.

FIG. 5 is a circuit diagram showing another example of a resonant capacitor in the voltage-controlled oscillator according to the first embodiment of the present invention.

FIG. 6 is a view showing a frequency characteristic before changing an inductance value by mutual induction in the case of using another example of a resonant capacitor in the voltage-controlled oscillator according to the first embodiment of the present invention.

FIG. 7 is a view showing a frequency characteristic after changing an inductance value by mutual induction in the case of using another example of a resonant capacitor in the voltage-controlled oscillator according to the first embodiment of the present invention.

FIG. 8 is a circuit diagram showing another example of a mutual-inductance circuit using a varicap as a load of a sub inductor for changing a value of a resonant inductance in the voltage-controlled oscillator according to the first embodiment of the present invention.

FIG. 9 is a circuit diagram showing another example of a mutual-inductance circuit using a varicap as a load of a sub inductor for changing a value of a resonant inductance in the voltage-controlled oscillator according to the first embodiment of the present invention.

FIG. 10 is a circuit diagram showing a configuration of a voltage-controlled oscillator according to a second embodiment of the present invention.

FIG. 11 is a circuit diagram showing a configuration of a voltage-controlled oscillator according to a third embodiment of the present invention.

FIG. 12 is a view showing oscillation stability by a Nyquist diagram before the inductance value is increased by the mutual induction in the voltage-controlled oscillator according to the third embodiment of the present invention.

FIG. 13 is a view showing oscillation stability by a Nyquist diagram after the inductance value is increased by the mutual induction in the voltage-controlled oscillator according to the third embodiment of the present invention.

FIG. 14 is a block diagram showing a W-CDMA direct conversion system according to a fourth embodiment of the present invention.

FIG. 15 is a diagram showing an example of a layout of the voltage-controlled oscillator according to the first embodiment of the present invention.

FIG. 16 is a diagram showing another example of a layout of the voltage-controlled oscillator according to the first embodiment of the present invention.

### DESCRIPTION OF THE PREFERRED EMBODIMENTS

A concept of the present invention is that objects of operating a plurality of frequency bands by one voltage-controlled oscillator or RF-IC and improving oscillation stability are achieved using an area smaller than those of a plurality of resonant circuits corresponding respectively to the frequency bands. The present invention is used, for example, in a wireless system such as a mobile terminal provided with a local oscillator inside a PLL system. Embodiments of the present invention will be described in detail below.

### First Embodiment

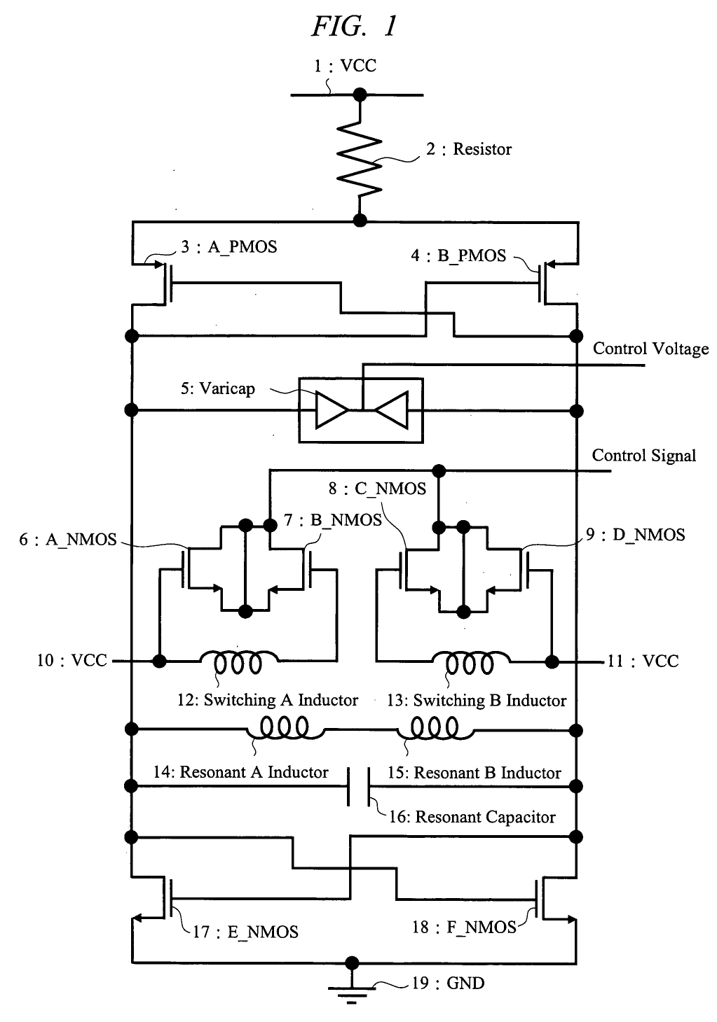

First, with reference to FIG. 1, an example of a configuration and operation of a voltage-controlled oscillator according to a first embodiment of the present invention will be described. FIG. 1 shows the configuration of the voltage-controlled oscillator according to the present embodiments. Note that a PMOS/NMOS transistor is merely abbreviated as a PMOS/NMOS.

The voltage-controlled oscillator according to the present embodiment is an oscillator (RF-IC) including a semiconductor integrated circuit formed on a semiconductor substrate, and comprises: a VCC 1 of a power supply potential; a resistor 2 that determines a value of a current flowing therein; a A_PMOS 3, a B_PMOS 4, an E_NMOS 17, and an F_NMOS 18 configuring a positive feedback circuit; a varicap 5 for changing an oscillation frequency; a resonant A inductor 14, a resonant B inductor 15, and a resonant capacitor 16 configuring a resonant circuit; a switching A inductor 12 and a switching B inductor 13 for changing an inductance value by mutual induction; an A_NMOS 6, a B_NMOS 7, a C_NMOS 8, and a D_NMOS 9 which are loads on a mutual inductor circuit; and a GND 19 of a ground potential.

Particularly, the A_NMOS 6, the B_NMOS 7, the C_NMOS 8, and the D_NMOS 9 each function as switch/load means, which have together a switching function of changing or increasing the inductance value by magnetic interactions between the resonant A inductor 14 and the resonant B inductor 15 and between the switching A inductor 12 and the switching B inductor 13, a load function of serving as loads of the switching A inductor 12 and the switching B inductor 13, and a function of changing a resonant-capacitance value. Also, the switching A inductor 12, the A_NMOS 6, and the B_NMOS 7 form one closed circuit, and the switching B inductor 13, the C_NMOS 8, and D_NMOS 9 also form one closed circuit.

The VCC 1 is connected to one end of the resistor 2. The other end of the resistor 2 is connected to source terminals of the A_PMOS 3 and the B_PMOS 4. Drain terminals of the A_PMOS 3 and the B_PMOS 4 are connected to drain terminals of the E_NMOS 17 and the F_NMOS 18, respectively. A gate terminal of the A_PMOS 3 is connected to the drain terminal of the B_PMOS 4. A gate terminal of the B_PMOS 4 is connected to the drain terminal of the A_PMOS 3.

Source terminals of the E_NMOS 17 and the F_NMOS 18 are connected to the GND 19. A gate terminal of the E_NMOS 17 is connected to the drain terminal of the F_NMOS 18. A gate terminal of the F_NMOS 18 is connected to the drain terminal of the E_NMOS 17.

The varicap 5, the resonant A inductor 14 and resonant B inductor 15 having been connected in series, and the resonant capacitor 16 are respectively connected between a line between the drain terminals of the A_PMOS 3 and the E_NMOS 17 and a line between the drain terminals of the B_PMOS 4 and the F_NMOS 18. To the varicap 5, a control voltage is applied.

Gate terminals of the A_NMOS 6 and the B_NMOS 7 are connected to terminals of the switching A inductor 12, respectively. Drain terminals of the A_NMOS 6 and the B_NMOS 7 are connected to each other and their source terminals are also connected. Concurrently, a line between the drain terminals and a line between the source terminals are also connected to each other. A VCC 10 is applied to the gate terminal of the A_NMOS 6, and a control signal is applied to the drain terminal thereof.

Gate terminals of the C_NMOS 8 and the D_NMOS 9 are connected to terminals of the switching B inductor 13, respectively. Drain terminals of the C_NMOS 8 and the C_NMOS 9 are connected to each other and their source terminals are also connected. Concurrently, a line between the drain terminals and a line between the source terminals are connected to each other. A VCC 11 is applied to the gate terminal of the C_NMOS 8, and the control signal is connected to the drain terminal thereof.

The above-configured voltage-controlled oscillator according to the present embodiment is an oscillation circuit for changing the oscillation frequency by: generating an alternate voltage across sub inductors of the switching A inductor 12 and the switching B inductor 13 and across loads of the A_NMOS 6, the B_NMOS 7, the C_NMOS 8, and the D_NMOS 9, the sub inductor changing a value of a resonant inductance; and changing respective resonance-inductance values of the resonant A inductor 14 and the resonant B inductor 15 through the mutual induction.

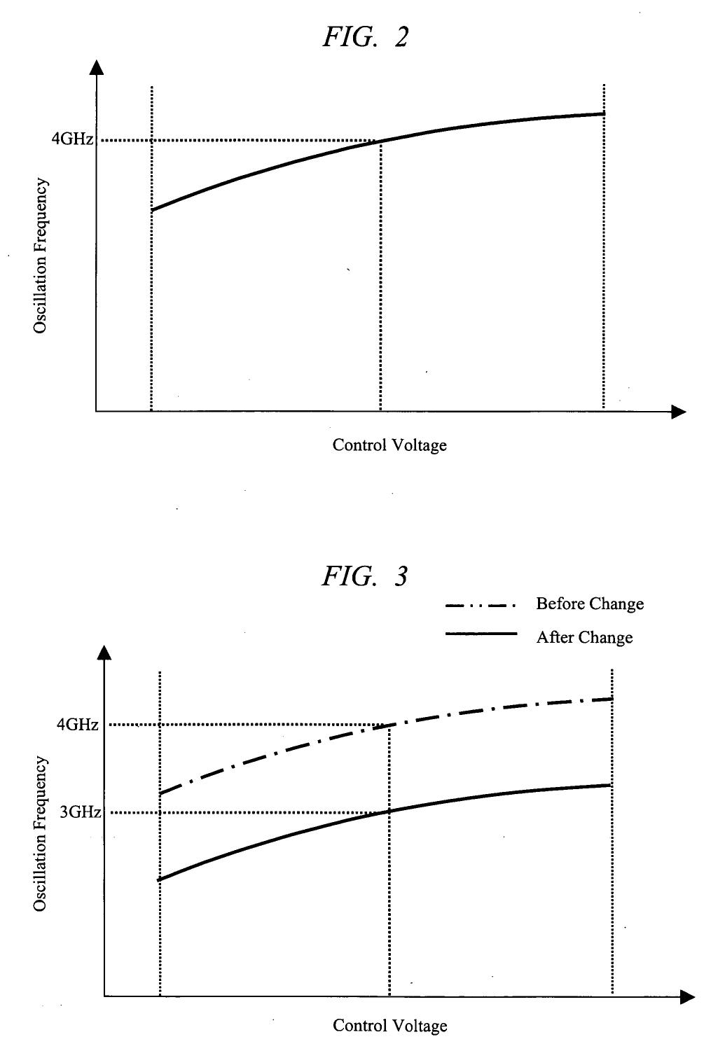

The operation of the voltage-controlled oscillator according to the present embodiment will be described below with reference to FIGS. 2 and 3. FIG. 2 shows a frequency characteristic before changing the inductance value by the mutual induction and FIG. 3 shows a frequency characteristic after changing the inductance value by the mutual induction. In the present embodiment, the operation of changing from an oscillation frequency of 4 GHz to 3 GHz will be described.

In this voltage-controlled oscillator, the A_PMOS 3 and the B_PMOS 4 configure one positive feedback circuit and the E_NMOS 17 and the F_NMOS 18 configure one positive feedback circuit, wherein negative resistance is generated between the respective drain terminals thereof. This negative resistance cancels parasitic resistance of a resonant circuit configured by the resonant B inductor 14, the resonant B inductor 15, the varicap 5, and the resonant capacitor 16, thereby playing a role of maintaining oscillation stability.

Here, a specific operation of the voltage-controlled oscillator will be described. If it is assumed that, in an initial state, the drain terminals of the E_NMOS 17 and the A_PMOS 3 have voltages higher than a DC bias voltage and the drain terminals of the F_NMOS 18 and the B_PMOS 4 have voltages lower than the DC bias voltage, the F_NMOS 18 has a gate-source voltage lower than a threshold of the F_NMOS 18, thereby becoming in an OFF state. Similarly, the B_PMOS 4 has a gate-source voltage higher than a threshold of the B_PMOS 4, thereby becoming in an OFF state. Meanwhile, the E_NMOS 17 has a gate-source voltage higher than a threshold of the E_NMOS 17, thereby becoming in an ON state. Similarly, the A_PMOS 3 has a gate-source voltage lower than a threshold of the A_PMOS 3, thereby becoming in an ON state. Thus, a drain current flows in each transistor. Each of the above four MOS transistors operates in a saturation region and, by repeating this ON/OFF operation, can output an oscillation signal with a constant amplitude.

Next, the operations before and at the frequency change will be described. First, before the frequency change, the control signal is turned OFF, and magnetic fluxes at the switching A inductor 12 and the switching B inductor 13 are varied with time. However, no alternate voltage is applied to the gate terminals of the A_NMOS 6, the B_NMOS 7, the C_NMOS 8, and the D_NMOS 9, and therefore no mutual inductance occurs. In this case, a change in the oscillation frequency by the control voltage is as shown in FIG. 2. The voltage-controlled oscillator of FIG. 1 can vary the capacitance by the control voltage applied to the varicap 5, and also vary the oscillation frequency accordingly.

Then, the operation at a time of changing the frequency will be described. At the time of changing the frequency, the control signal is turned ON, whereby the magnetic fluxes at the switching A inductor 12 and the switching B inductor 13 are varied with time and alternate voltages are applied to the gate terminals of the A_NMOS 6, the B_NMOS 7, the C_NMOS 8, and the D_NMOS 9. In this configuration, the values of the resonant A inductor 14 and the resonant B inductor 15 are increased with this mutual induction. Since the oscillation frequency is represented by ½π\sqrt{LC}, the oscillation frequency is decreased by this mutual induction, whereby the change in the oscillation frequency by the control voltage is shown in FIG. 3. As described above, since the inductance value is changed by the mutual induction, the changing of the oscillation frequency becomes possible, so that deterioration in the Q factor due to parasitic components involving reduction of the area of the capacitor and addition of the capacitor can be suppressed in comparison with the case of switching the capacitor.

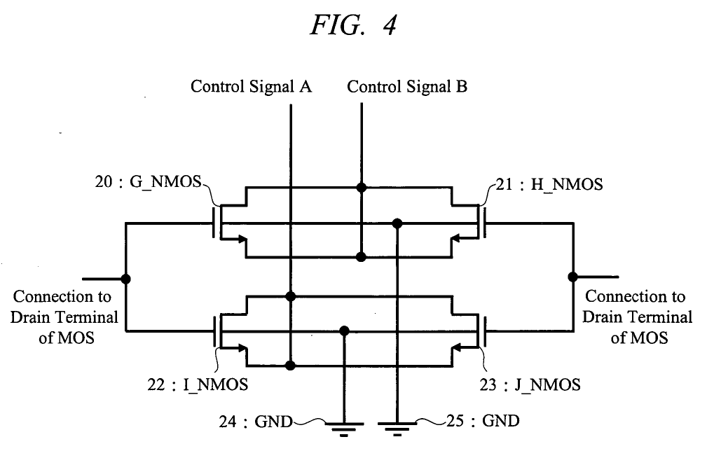

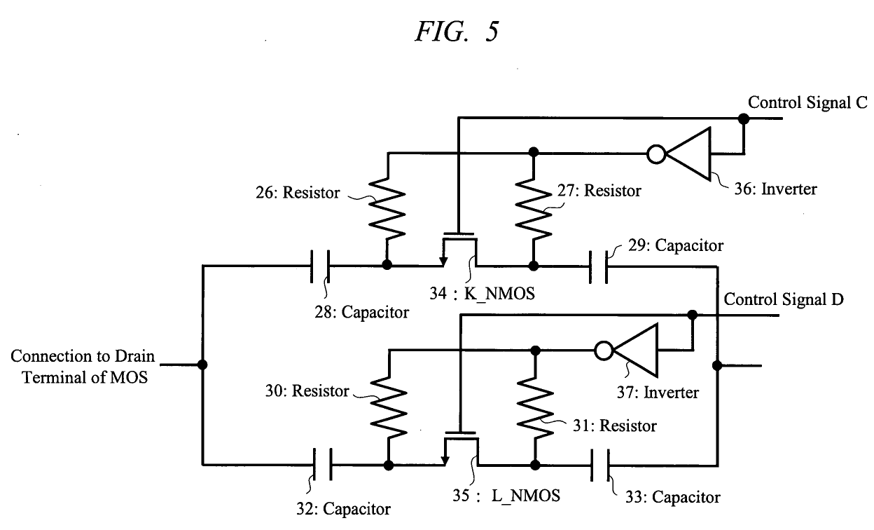

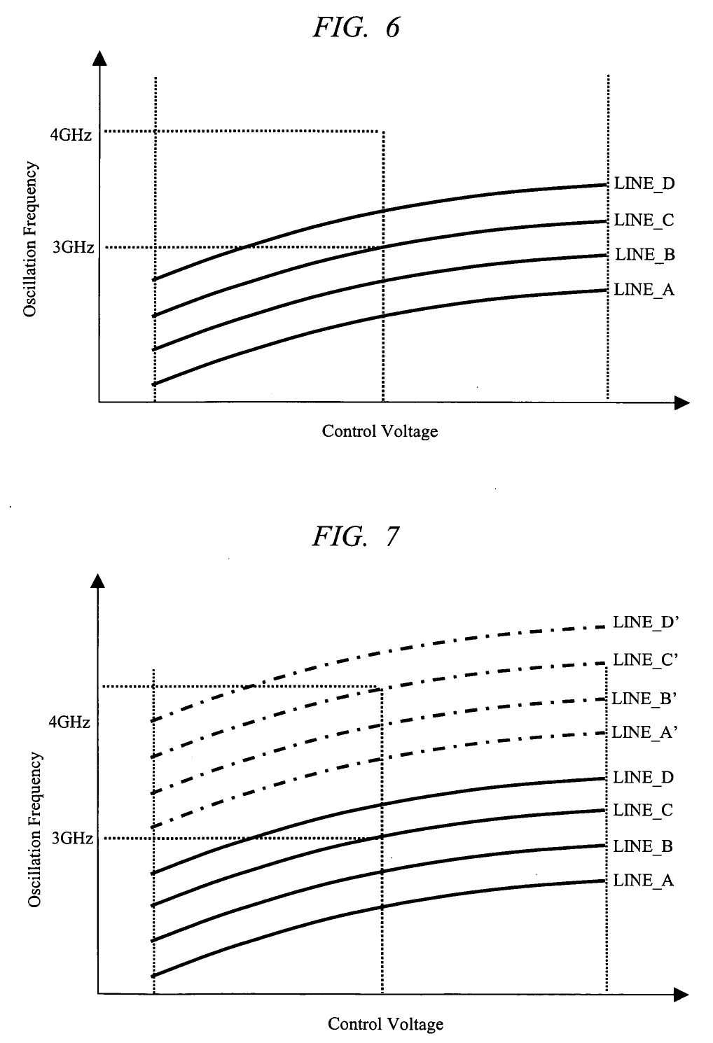

Also, in the voltage-controlled oscillator according to the present embodiment, the resonant capacitor 16 shown in FIG. 1 can be replaced with that as shown in FIG. 4 or 5. In this case, a frequency characteristic before changing the inductance value by the mutual induction is shown in FIG. 6 while a frequency characteristic after changing it is shown in FIG. 7.

First, the resonant capacitor shown in FIG. 4 will be described. The resonant capacitor of FIG. 4 comprises a G_NMOS 20, an H_NMOS 21, an I_NMOS 22, a J_NMOS 23, a GND 24, and a GND 25. Here, the G_NMOS 20 and H_NMOS 21 are different in transistor size and number of transistors from the I_NMOS 22 and J_NMOS 23, and it is assumed that the G_NMOS 20 and H_NMOS 21 are larger in transistor size and number of transistors than the I_NMOS 22 and J_NMOS 23, respectively.

The operation of the resonant capacitor will be described below with reference to FIG. 6. When a control signal A and a control signal B are in LOW states, forward biases are applied between the gate terminals of the respective MOS transistors, between the source terminals thereof, and between the drain terminals thereof, whereby the transistors are turn ON. Therefore, by the capacitance of the MOS transistor and the inductance values of the resonant A inductor 14 and the resonant B inductor 15, the oscillation frequency of the VCO is represented by a LINE_A in FIG. 6.

Next, when the control signal A becomes in a HIGH state and the control signal B becomes in a LOW state, reverse biases are applied between the gate terminals of the I_NMOS 22 and the J_NMOS 23, between the source terminals thereof, and between the drain terminals thereof, so that the MOS transistors are turned OFF. Meanwhile, the forward biases are applied between the gate terminals of the G_NMOS 20 and the H_NMOS 21, between the source terminals thereof, and between the drain terminals thereof, so that the MOS transistors are turned ON. Therefore, since the overall capacitance of the resonant circuit is decreased, the oscillation frequency is higher than that represented by the LINE_A and is shown by a LINE_B of FIG. 6.

Similarly, when the control signal A becomes in a LOW state and the control signal B becomes in a HIGH state, the forward biases are applied between the gate terminals of the I_NMOS 22 and the J_NMOS 23, between the source terminals thereof, and between the drain terminals thereof, whereby the MOS transistors are turned ON. Meanwhile, the reverse biases are applied between the gate terminals of the G_NMOS 20 and the H_NMOS 21, between the source terminals thereof, and between the drain terminals thereof, whereby the MOS transistors are turned OFF. Thus, the overall capacitance of the resonant circuit is decreased. At this time, the capacitances of the G-NMOS 20 and the H-NMOS 21 are larger than those of the I_NMOS and the J_NMOS, so that the capacitance of the resonant circuit is smaller than that under the condition represented by the LINE_B. Therefore, the oscillation frequency is shown in a LINE_C of FIG. 6.

Also, when the control signal A is in a HIGH state and the control signal B is in a HIGH state, the reverse biases are applied between the gate terminals of the I_NMOS 22 and the J_NMOS 23, between the source terminals thereof, and between the drain terminals thereof, i.e., between the gate terminals of the transistors, between the source terminals thereof, and between the drain terminals thereof. Accordingly, all the MOS transistors are turned OFF and the overall capacitance of the resonant circuit is minimized, so that the oscillation frequency is represented by a LINE_D of FIG. 6.

Subsequently, the resonant capacitor shown in FIG. 5 will be described. The resonant capacitor of FIG. 5 comprises resistors 26, 27, 30, and 31, capacitances 28, 29, 32, and 33, and a K_NMOS 34 and an L_NMOS 35 serviced as switches, and inverters 36 and 37. It is assumed therein that the capacitance values of the capacitances 28, 29, 32, and 33 are different from one another.

The operation of the resonant capacitor will be described below with reference to FIG. 6. When a control signal C and a control signal D are both in HIGH states, the K_NMOS 34 and the L_NMOS 35 are turned ON. In this case, the control signals C and D in the HIGH states are outputted as LOW states from the inverters 36 and 37, respectively. To the voltages outputted in the LOW states from the inverters, LOW voltages are applied via the resistors 26 and 27 and the resistors 30 and 31, respectively. Since the bias voltages are applied to the capacitances 28 and 29 and the capacitances 32 and 33 from the drain terminals of the MOSs, the overall capacitance of the resonant circuit becomes maximized. Therefore, the oscillation frequency is represented by the LINE_A of FIG. 6.

Similarly, when the control signal D is in the HIGH state and the control signal C is in the LOW state, the L_NMOS 35 is turned OFF and the control signal D is outputted as the HIGH state from the inverter 37 and is then applied via the resistors 30 and 31 to the VCC voltage. At this time, the voltages are applied to the capacitances 32 and 33 from both respective sides, so that these capacitances do not seem to serve as capacitances. Meanwhile, the K_NMOS is turned ON and becomes in a GND state with respect to the capacitances 32 and 33 from the drain terminals of the MOSs. On the other hand, the K_NMOS 34 is tuned OFF, the control signal C is outputted as a LOW state from the inverter 36, and a LOW voltage is applied via the resistors 26 and 27 to the outputted voltage. At this time, the capacitances 28 and 29 seem to serve as a GND capacitance pair. Since the overall capacitance of the resonant circuit is decreased, the oscillation frequency is represented by the LINE_B of FIG. 6.

Similarly, when the control signal D is in the LOW state and the control signal C is in the HIGH state, the L_NMOS 35 is turned ON and the control signal D is outputted as a LOW state from the inverter 37 and is then applied via the resistors 30 and 31 to a LOW voltage. At this time, since a voltage is applied to one side of each of the capacitances 32 and 33, the capacitances seem to serve as a GND capacitance pair. Meanwhile, the K_NMOS 34 is turned OFF, and the VCC voltage is applied to the capacitances 32 and 33 from the drain terminals of the MOSs, whereby the capacitances do not seem to serve as capacitances. Here, since the capacitances 28 and 29 are larger than the capacitances 32 and 33, the capacitance of the resonant circuit is smaller than that under the condition represented by the LINE_B. Therefore, the oscillation frequency is shown in the LINE_C of FIG. 6.

Still further, when the control signals C and D are in the HIGH states, the L_NMOS 35 and the K_NMOS 34 are both turned OFF and the control signal C is applied to the VCC voltage via the resistors 26 and 27 while the control signal D is applied to the VCC voltage via the resistors 30 and 31. Since the voltages are applied to both sides of each of the capacitances 28 and 29 and to both sides of each the capacitances 32 and 33, these capacitances do not seem to serve as capacitances. Since the overall capacitance of the resonant circuit is minimized, the oscillation frequency is represented by the LINE_D of FIG. 6.

The oscillation frequency is variable even when the resonant capacitor of FIG. 4 or 5 is used. The state of change in the oscillation frequency in this case is shown in FIG. 7. That is, the LINE_A, the LINE_B, the LINE_C, and the LINE D can be shifted in frequency to a LINE_A′, a LINE_B′, a LINE_C′, and a LINE D′, respectively.

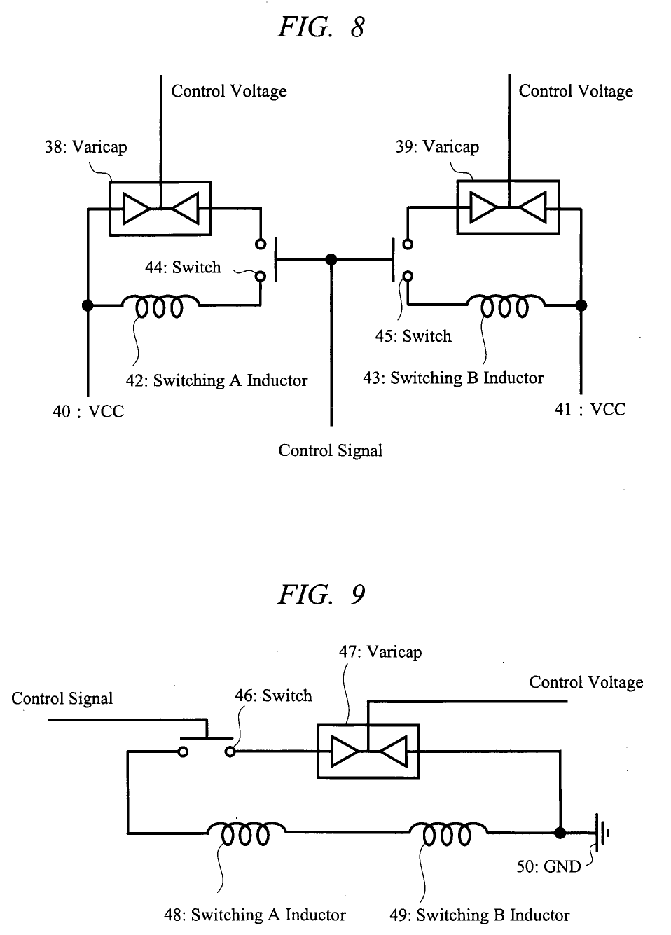

Also, in the voltage-controlled oscillator according to the present embodiment, the loads on the sub inductors can be replaced as shown in FIG. 8 or 9.

FIG. 8 shows that the loads are replaced by varicaps 38 and 39 connected to VCCs 40 and 41. Switches 44 and 45 are turned ON by the control signal, and the alternate voltage is applied to the varicaps 38 and 39 by a switching A inductor 42 and a switching B inductor 43, respectively. Thereby, the mutual induction is created and the resonant-inductance values can be changed. Also, since the capacitance value can be varied by applying the control voltages to the varicaps 38 and 39, the oscillation frequency can be also varied.

In FIG. 9, one terminals of a switching A inductor 48 and a switching B inductor 49 are connected, and the other terminals thereof are set at a GND 50. As with FIG. 8, a switch 46 is turned ON by the control signal, and the alternate voltage is applied to a varicap 47 by the switching A inductor 48 and the switching B inductor 49. Thereby, the mutual induction is created and the resonant inductance values can be changed. Also, since the control voltage of the varicap 47 is variable, the resonant inductance values can be varied.

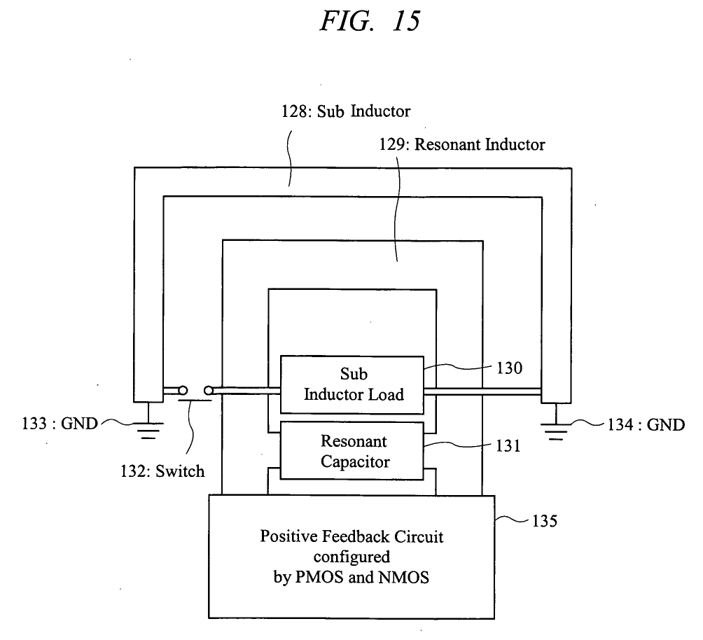

FIG. 15 shows one example of a layout according to the present embodiment. In this example, the switching A inductor and the switching B inductor are combined together to form a sub inductor 128 for changing a value of a resonant inductance. Similarly, the resonant inductor A and the resonant inductor B are combined together to form a resonant inductor 129. In the present embodiment, the sub inductor 128 and the resonant inductor 129 are both formed into “]” shapes. One side of the sub inductor is connected to a GND 133 and the other side thereof is connected to a GND 134. Since the sub inductor 128 and the resonant inductor 129 are formed in “]” shapes, resistance components are reduced by increasing wiring width and the Q factor is increased. Therefore, oscillation stability can be increased. Of course, the sub inductor 128 and the resonant inductor 129 may be formed into other shapes. In the present embodiment, in order to suppress the parasitic capacitances added to a sub inductor load 130 and a resonant capacitor 131 and prevent the oscillation frequency from shifting, the sub inductor load 130 and the resonant capacitor 131 are disposed at a base of the resonance inductor. A positive feedback circuit 135 disposed under them and configured by the NMOS and PMOS and a switch 132 for changing the frequency are connected to the sub inductor 128 from a left side of the sub inductor load. Alternatively, these components may be placed at other positions without considering effects on the shift in oscillation frequency.

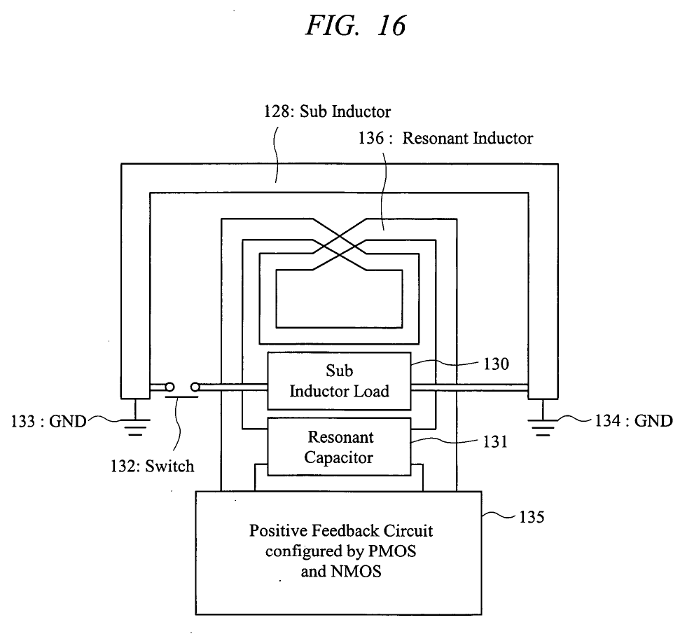

FIG. 16 shows another example of the layout according to the present embodiment. The basic constitution of this example is identical to that of the above example, but is different therefrom in the shape of a resonant inductor 136. By forming the resonant inductor 136 into a spiral shape as shown in this example, the wiring width is narrowed, whereby an area can be reduced. Of course, the resonant inductor 136 may be formed into another shape. Similarly, the shape of the sub inductor 128 is not limited to the “]” shape and may be another shape.

Therefore, according to the voltage-controlled oscillator of the present embodiment, the alternate voltages are generated in the sub inductor and the load by the control signal and the inductance value is changed by the mutual induction, so that a frequency range wider than the oscillation frequency changing range obtained by the variable capacitance and the fixed capacitance can be taken. Also, since the inductance value is increased by the mutual induction, the oscillation stability can be improved.

### Second Embodiment

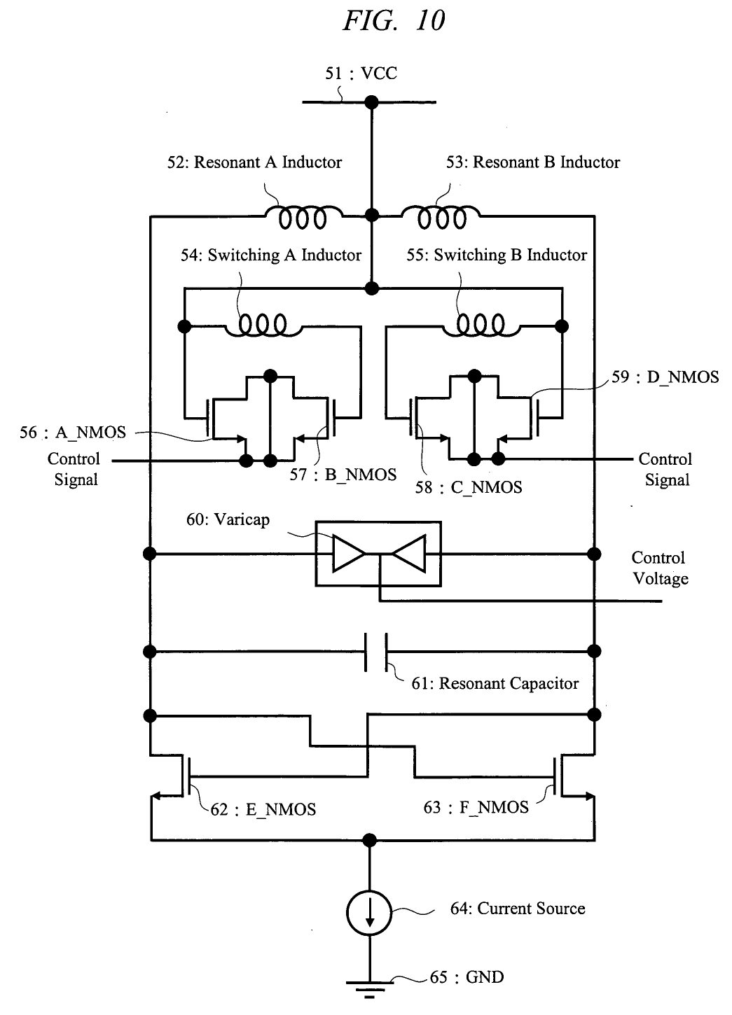

With reference to FIG. 10, examples of a configuration and an operation of a voltage-controlled oscillator according to a second embodiment of the present invention will be described. FIG. 10 shows a configuration of the voltage-controlled oscillator according to the present embodiment.

As with the first embodiment, a voltage-controlled oscillator according to the present embodiment is an oscillator (RF-IC) configured by a semiconductor integrated circuit formed on a semiconductor substrate, and includes: a VCC 51 of a power supply potential; a current source 64 that determines a current flowing therein; an E_NMOS 62 and an F_NMOS 63 configuring a positive feedback circuit; a varicap 60 for changing the oscillation frequency; a resonant A inductor 52, a resonant B inductor 53, and a resonant capacitor 61 configuring a resonant circuit; a switching A inductor 54 and a switching B inductor 55 for changing inductance values by mutual induction; an A_NMOS 56, a B_NMOS 57, a C_NMOS 58, and a D_NMOS 59 serving as loads of a mutual inductance circuit; and a GND 65 of a ground potential.

This voltage-controlled oscillator is an oscillator circuit for changing the oscillation frequency by: generating the alternate voltages at the sub inductors and loads by the control signals; and changing the resonance inductance value by the mutual induction. The present embodiment is different from the first embodiment only in that no PMOS transistors are used, so that no PMOS transistor operation is included in the circuit operation. Therefore, the circuit operation except the PMOS transistor operation in this embodiment is much identical to that of the first embodiment, so that the detailed description will be omitted.

Therefore, even in the voltage-controlled oscillator according to the present embodiment, as with the first embodiment, by changing the inductance value by the mutual induction, the frequency range wider than the oscillation frequency changing range based on the variable capacitance or the fixed capacitance can be taken. Also, by increasing the inductance vales by the mutual induction, the oscillation stability can be improved.

### Third Embodiment

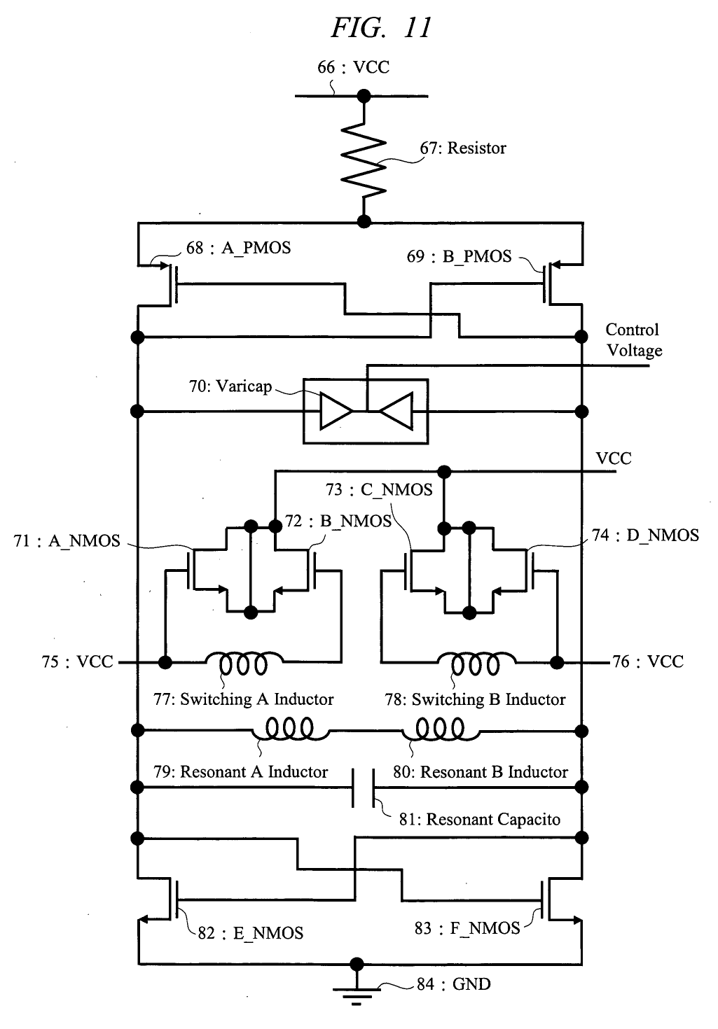

With reference to FIG. 11, examples of a configuration and an operation of a voltage-controlled oscillator according to a third embodiment of the present invention will be described. FIG. 11 shows a configuration of the voltage-controlled oscillator according to the present embodiment.

The voltage-controlled oscillator of this embodiment is identical in circuit configuration to that of the first embodiment, except for a system of feeding the control signal.

That is, the voltage-controlled oscillator of this embodiment includes a VCC 66 of a power supply potential; a resistor 67 for regulating a value of a current flowing therein; an A_PMOS 68, a B_PMOS 69, an E_NMOS 82, and an F_NMOS 83 configuring a positive feedback circuit; a varicap 70 for changing the oscillation frequency; a resonant A inductor 79, a resonant B inductor 80, and a resonant capacitor 81 configuring a resonant circuit; a switching A inductor 77 and a switching B inductor 78 for changing the inductance value by the mutual induction; an A_NMOS 71, a B_NMOS 72, a C_NMOS 73, and a D_NMOS 74 serving as loads of a mutual-inductance circuit; and a GND 84 of a ground potential.

In this configuration of the voltage-controlled oscillator, instead of being turned ON/OFF by the control signal, a VCC 75 is supplied to gate and drain terminals of the A_NMOS 71 and the B_NMOS 72 and a VCC 76 is supplied to gate and drain terminals of the C_NMOS 73 and the D_NMOS 74, so that the mutual induction is always created. By this mutual induction, the resonant A inductor 79 and the resonant B inductor 80 can obtain inductance values higher than those of the resonant A inductor 79 and the resonant B inductor 80, respectively. In stability of the oscillator, Q of the resonant circuit becomes dominant. The Q factor in the inductor is “Q=2πfL/r”, that is, proportional to “a frequency f×an inductance value L” and inversely proportional to a parasitic resistance r. When the inductance value is increased by the mutual induction, an increase in the parasitic resistance added to the inductor can be suppressed and the inductance value can be increased.

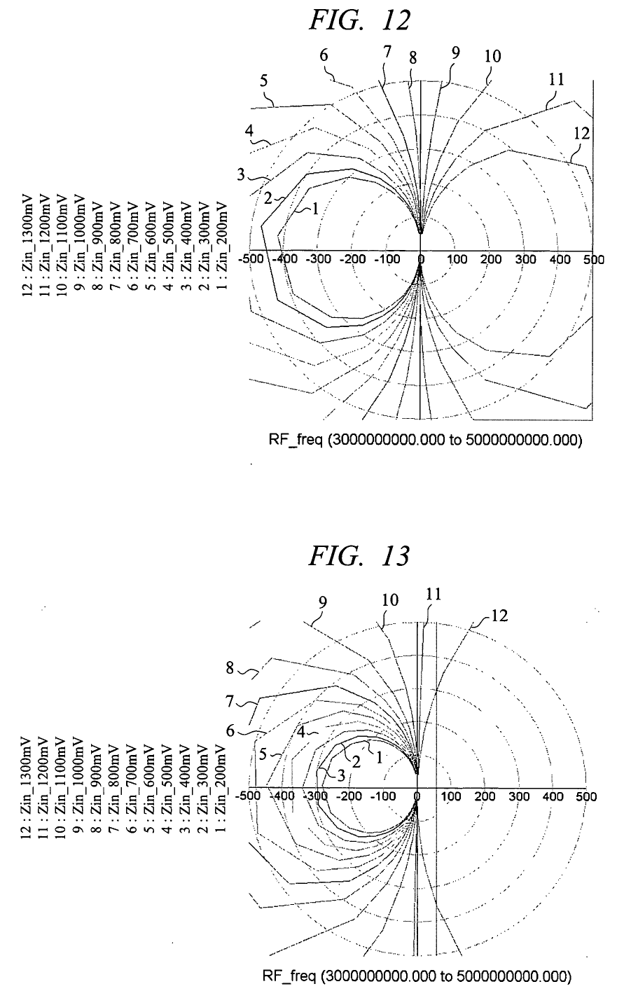

FIGS. 12 and 13 show Nyquist diagrams serving as indicators of oscillation stability when the inductance value is changed to 0.4593 nH and the inductance value is changed to 1.792 nH by the mutual induction, respectively. The Nyquist diagram represents impedance at a certain frequency, wherein the horizontal and vertical axes represent the real and imaginary numbers of the impedance, respectively. Also, one curve represents an amplitude level oscillated at the output terminal of the oscillation circuit, so that as the amplitude level is higher, the oscillation stability condition is stricter. When the oscillation operation is performed at the desired amplitude level, the relevant Nyquist curve requires surrounding (−1, 0) on the left half-plane on the Nyquist diagram. FIGS. 12 and 13 show simulation results of the oscillation stability by a high-frequency circuit simulator ADS. The oscillation frequency of the oscillation circuit was set to 3.6 GHz.

In FIG. 12, curves with amplitude levels of 200 mV to 900 mV are present on the left plane of the Nyquist diagram, so that the oscillation stability is satisfied. However, curves with amplitude levels of 1000 mV or higher are present on the right plane of the Nyquist diagram, so that the oscillation stability is not satisfied. In contrast, in FIG. 13 in which the inductance values are increased by the mutual induction, curves with amplitude levels of 200 mV to 1100 mV are present on the left plane of the Nyquist diagram, so that the oscillation stability is satisfied. This indicates that the oscillation stability can be ensured even at higher output levels. As described above, the Q factor is increased by increasing the inductance value by the mutual induction, whereby the oscillation stability of the oscillation circuit can be further improved.

Therefore, even in the voltage-controlled oscillator according to the present embodiment, as with the first embodiment, by changing the inductance value by the mutual induction, a frequency range wider than the oscillation frequency changing range obtained by the variable capacitance or fixed capacitance can be taken. Also, by increasing the inductance value by the mutual induction, the oscillation stability can be improved and, particularly, the oscillation stability of the oscillation circuit can be further improved.

### Fourth Embodiment

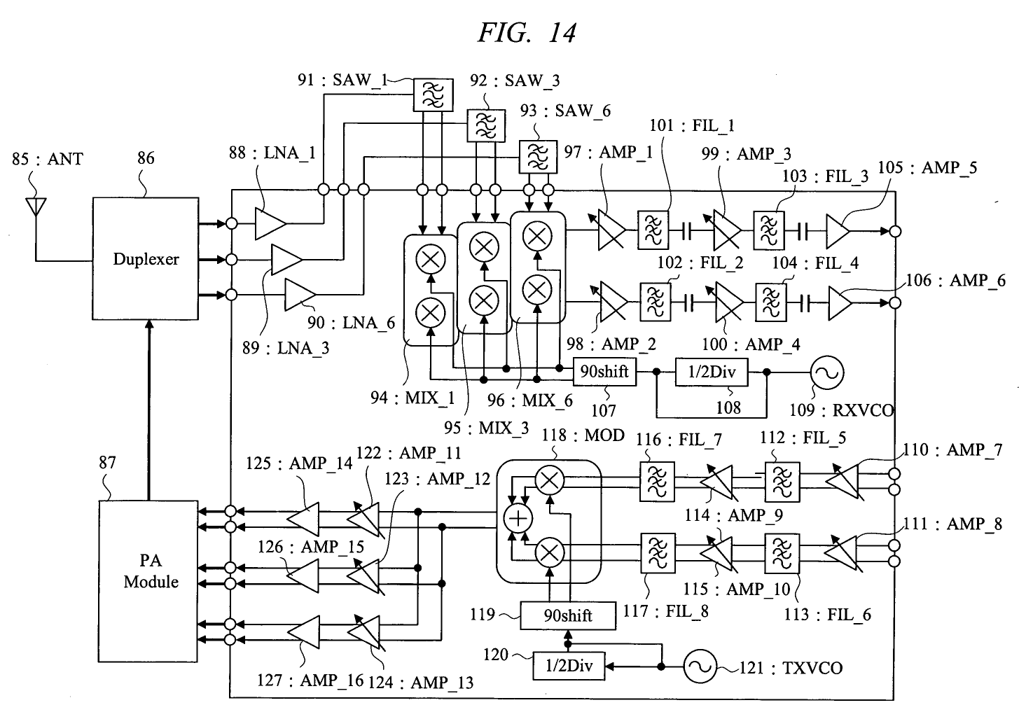

With reference to FIG. 14, examples of a configuration and an operation of a W-CDMA direct conversion system according to a fourth embodiment of the present invention will be described. FIG. 14 shows a configuration of the W-CDMA direct conversion system according to the present embodiment. Receiving and transmitting operations of the present system will be described below.

The W-CDMA direct conversion system according to the present embodiment covers three frequency bands, that is, Band 1, Band 3, and Band 6 (2 GHz, 1.7 GHz, and 800 MHz bands). In this case, transmission and reception in Band 1 will be mainly described.

First, a flow of a reception signal is shown. The reception signal is received at an antenna ANT 85 and is inputted to a Duplexer 86 for ensuring isolation of a transmission signal and the reception signal. Since the inputted signal is isolated from a transmitting system, it is prevented from leaking to a PA Module 87 at a high level. When the reception signal is a signal of the Band 1, it is subjected to low noise amplification at an LNA 1 88 and an interfering-wave removal at an SAW_1 91 and is then inputted to a MIX_1 94. A reception signal of Band 3 is subjected to low noise amplification at an LNA_3 89 and an interfering-wave removal at an SAW_3 92 and is then inputted to a MIX_3 95. A reception signal of Band 6 is subjected to low noise amplification at an LNA_6 90 and an interfering-wave removal at an SAW_6 93 and is then inputted to a MIX_6 96. Meanwhile, a local signal is outputted from an RXVCO 109. The RXVCO 109 can cover the frequencies of the Band 1, Band 3, and Band 6, and its operation has been described in the above first to third embodiments and therefore is not described herein. The RXVCO 109 outputs a double frequency (4 GHz band) of the Band 1, is converted into the same frequency as that of the Band 1, and is 90-degree shifted to be outputted to the MIX_1 94. The same occurs about the Band 3. As for the Band 6, in order to convert the frequency of the local signal to a 800 MHz band, the frequency is divided in advance by a ½ Div 108. At the MIX_1 94, the reception signal and the local signal are frequency-converted to a baseband signal. The baseband signal is amplified to an appropriate level at an AMP_1 97, an AMP_2 98, an AMP_3 99, an AMP_4 100, an AMP_5 105, and an AMP_6 106, is subjected to an interfering-wave removal at a FIL_1 101, a FIL_2 102, a FIL_3 103, and a FIL_4 104, and is then outputted to the outside of an IC.

Next, the transmitting operation will be described. A baseband signal inputted from the outside of the IC is amplified to an appropriated level at an AMP_7 110, an AMP_8 111, an AMP_9 114, and an AMP_10 115, is subjected to an interfering-wave removal at a FIL_5 112, a FIL_6 113, a FIL_7 116, and a FIL_8 117, and is then inputted to a MOD 118. Meanwhile, a local signal is outputted from a TXVCO 121. The TXVCO 121 can cover the frequencies of the Band 1, Band 3, and Band 6, and its operation has been described in the above first to third embodiments and therefore is not described herein. The TXVCO 121 outputs a double frequency (4 GHz band) of the Band 1. The frequency is converted into the same frequency as that of the Band 1 by a 90-degree shifter 119, and is 90-degree shifted to be outputted to the MOD 118. The same occurs about the Band 3. However, as for the Band 6, in order to convert the frequency of the local signal into a 800 MHz band, the frequency is divided in advance by the ½ Div 108. The baseband signal and the local signal are modulated by the MOD 118. Signal processings after modulation depend on the Bands. For the Band 1, the signal is amplified by an AMP_11 122 and an AMP_14 125 to an appropriate level. For the Band 3, the signal is amplified by an AMP_12 123 and an AMP_15 126. For the Band 6, the signal is amplified by an AMP_13 124 and an AMP_16 127. The amplified signals are further amplified by the PA Module 87 to predetermined levels and are then outputted via the Duplexer 86 from the ANT 85. Since the isolation of the transmission signal and the reception signal is ensured in the Duplexer 86, the transmission signal is prevented from leaking to a receiving system at a high level.

As described above, in the W-CDMA direct conversion system according to the present embodiment, since the oscillator covering all of the relevant frequency bands is disposed, the area conventionally occupying a considerable portion of the IC can be significantly reduced.

As described above, the invention made by the present inventors has been specifically explained based on the embodiments. However, needless to say, the present invention is not limited to the above-mentioned embodiments and can be variously modified within the scope of not departing from the gist thereof.

As for industrial applicability, the present invention relates to the voltage-controlled oscillator and, particularly, is effectively applied to the voltage-controlled oscillator and the RF-IC for W-CDMA, which include the semiconductor integrated circuit formed on the semiconductor substrate. For example, the present invention can be used in the wireless system for mobile terminal or the like having the local oscillator inside the PLL system.

What is claimed is:

1. A voltage-controlled oscillator, which is provided with a resonant circuit configured by a resonant inductor and a resonant capacitance, and an active component forming negative resistance and is formed on a semiconductor substrate, the voltage-controlled oscillator comprising:
a sub inductor for changing a value of a resonant inductance and generating a magnetic interaction with said resonant inductor; and
switching/load means having together a switching function of changing an inductance value by the magnetic interaction between said resonant inductor and said sub inductor, a load function of serving as a load of said sub inductor, and a function of changing a value of said resonant capacitance,
wherein an oscillation frequency is switched by changing said inductance value and said value of the resonant capacitance.

2. An voltage-controlled oscillator, which is provided with a resonant circuit configured by a resonant inductor and a resonant capacitance, and an active component forming negative resistance and is formed on a semiconductor substrate, the voltage-controlled oscillator comprising:
a sub inductor for changing a value of a resonant inductance and generating a magnetic interaction with said resonant inductor; and
switching/load means having together a switching function of increasing an inductance value by the magnetic interaction between said resonant inductor and said sub inductor, and a load function of serving as a load of said sub inductor,
wherein oscillation stability is improved by increasing said inductance value.

3. The voltage-controlled oscillator according to claim 1,
wherein a circuit formed by said sub inductor and said switch/load means is a closed circuit.

4. The voltage-controlled oscillator according to claim 2,
wherein a circuit formed by said sub inductor and said switch/load means is a closed circuit.

5. The voltage-controlled oscillator according to claim 1,
wherein said negative resistance is formed by one of an NMOS/PMOS transistor and an NPN/PNP transistor.

6. The voltage-controlled oscillator according to claim 2,
wherein said negative resistance is formed by one of an NMOS/PMOS transistor and an NPN/PNP transistor.

7. The voltage-controlled oscillator according to claim 1,
wherein said resonant capacitance is formed by a variable capacitance and a fixed capacitance.

8. The voltage-controlled oscillator according to claim 3,
wherein said switch/load means are formed by one of a varicap and an NMOS/PMOS transistor.

9. The voltage-controlled oscillator according to claim 3,
wherein said switch/load means are formed by a MOS transistor.

10. An RF-IC of W-CDMA system comprising:
an inductance of a controlled oscillator generating a local signal to be supplied to a direct-down MIXER or a direct-up MIXER; and
a primary coil and a secondary coil M-coupled to each other, the inductance configured by the primary coil and the secondary coil,
wherein an oscillation of a high frequency is determined by an inductance of the primary coil and an oscillation of a low frequency is determined by the primary coil and secondary coil and a mutual inductance.

11. An RF-IC of W-CDMA system
an inductance of a controlled oscillator generating a local signal to be supplied to a direct-down MIXER or a direct-up MIXER; and
a primary coil and a secondary coil M-coupled to each other, the inductance configured by the primary coil and the secondary coil,
wherein oscillation stability of a low frequency is improved by the primary coil and secondary coil and a mutual inductance.
